(19) United States
(12) Patent Application Publication
(10) Pub. No.: US 2013/0240035 A1
(43) Pub. Date: Sep. 19, 2013

(54) SOLAR CELL PROTECTIVE SHEET AND METHOD FOR PRODUCING SAME, BACK SHEET FOR SOLAR CELL, AND SOLAR CELL MODULE

(71) Applicant: FUJIFILM CORPORATION, Tokyo (JP)

(72) Inventors: Ryota SUZUKI, Kanagawa (JP); Yohei ARITOSHI, Kanagawa (JP); Yusuke AKASAKI, Kanagawa (JP)

(73) Assignee: FUJIFILM Corporation, Tokyo (JP)

(21) Appl. No.: 13/889,801

(22) Filed: May 8, 2013

Related U.S. Application Data
(63) Continuation of application No. PCT/JP2011/075487, filed on Nov. 4, 2011.

(30) Foreign Application Priority Data
Nov. 9, 2010 (JP) 2010-251204

(51) Int. Cl. H01L 31/048; H01L 31/18

(52) U.S. Cl. CPC H01L 31/0487; H01L 31/18
USPC 136/259; 428/421; 428/336; 427/223; 427/536

(57) ABSTRACT

A solar cell protective sheet comprising a polyethylene terephthalate-containing substrate that has been surface-treated through flame treatment with a silane compound-introduced flame or through atmospheric-pressure plasma treatment, and having, on the treated surface of the substrate, a coating layer that contains a fluoropolymer, has good interlayer adhesiveness after wet heat aging.

### CROSS-REFERENCE TO RELATED APPLICATIONS

This application is a continuation application of International Application No. PCT/JP2011/075487, filed Nov. 9, 2011, which in turn claims the benefit of priority from Japanese Application No. 2010-251204, filed Nov. 9, 2010, the disclosures of which Applications are incorporated by reference herein in their entirety.

### BACKGROUND OF THE INVENTION

1. Field of the Invention

The present invention relates to a solar cell protective sheet excellent in interlayer adhesiveness after wet heat aging and to its production method, and relates to a back sheet for solar cells and a solar cell module using the solar cell protective sheet.

2. Description of the Related Art

A solar cell module generally has a configuration in which sealant/solar cell element/sealant/back sheet (hereinafter this may be referred to as BS) are laminated in that order on glass or front sheet on which sunlight falls. Concretely, the solar cell element is generally so configured that it is buried in a resin (sealant) such as EVA (ethylene/vinyl acetate copolymer) or the like and a solar cell protective sheet is stuck thereonto. As the solar cell protective sheet, heretofore used is a polyester film, especially a polyethylene terephthalate (hereinafter referred to as PET) film.

However, when an ordinary PET film is used as a solar cell protective sheet, especially as a back sheet (BS) to be the outermost layer for solar cells for a long period of time, it may readily break or peel on the solar cells, and BS of a monolayer PET film often peels from the sealant such as EVA or the like when left in the environment such as outdoors or the like where it is exposed to weather for a long period of time. Against the problem of weather resistance degradation, heretofore mainly used is a laminate-type BS produced by bonding a weather-resistant film to the outermost layer side of the substrate film of PET or the like. For those bonded laminates, a fluoropolymer film such as a polyvinyl fluoride film or the like is most popularly used. As the solar cell back sheet using a fluoropolymer film, for example, there are mentioned a composite film of a fluoropolymer film and a metal foil; and a laminate of a fluoropolymer film, a silicon oxide thin film layer and a transparent resin (for example, see PATENT DOCUMENT 1), etc.

However, in case where a fluoropolymer film is used as a laminate-type back sheet for solar cells, the interlayer adhesiveness (bonding) between the polyester film and the fluoropolymer film is poor, therefore causing a problem of delamination in long-term use. Against this, as a technique for solving the problem with the fluoropolymer film mentioned above, recently, there has been developed a coating layer-having back sheet produced by coating a PET substrate film with a fluoropolymer-containing composition (see PATENT DOCUMENTS 2 to 4). For example, PATENT DOCUMENTS 2 and 3 disclose a solar cell back sheet produced by directly coating a polyester substrate film with a curable functional group-having fluoropolymer coating material to form a cured coating film thereon, and a sheet coated with a fluoropolymer solution that contains conventional known crosslinking agent and curing agent added thereto. On the other hand, PATENT DOCUMENT 4 discloses in Examples therein, a case of surface-treating a substrate PET in place of using a crosslinking agent, in which the substrate PET is surface-treated through corona treatment and then coated with a fluoropolymer to give a coated sheet.

In addition to corona treatment, flame treatment and glow discharge treatment described in PATENT DOCUMENT 4 regarding the surface treatment technique to be applied to such a fluoropolymer, PATENT DOCUMENT 5 describes a method of irradiation with special electromagnetic waves and plasma treatment, and discloses in Examples therein, embodiments of a method of irradiating with special electromagnetic waves under a low-pressure condition near to vacuum, and plasma treatment.

### CITATION LIST

PATENT DOCUMENT 1: JP-A 4-239634
PATENT DOCUMENT 2: JP-A 2007-35694
PATENT DOCUMENT 3: WO2008/143719
PATENT DOCUMENT 4: JP-A 2010-053317
PATENT DOCUMENT 5: JP-A 2002-282777

### SUMMARY OF THE INVENTION

Given the situation, the present inventors investigated the methods described in PTL 2 to 4, and have known that the polyester films described in these references could be bettered in some degree in point of the interlayer adhesiveness thereof after aging under ordinary conditions but the interlayer adhesiveness thereof after wet heat aging is still bad, and therefore the films are still unsatisfactory from the viewpoint of long-term storability in high-temperature high-humidity environments required in applying the films to solar cells.

The present invention has been made in consideration of the above-mentioned situation, and the technical problem which the invention is to solve is to provide a solar cell protective sheet having good interlayer adhesiveness after wet heat aging and a production method for the solar cell protective sheet.

The present inventors assiduously studied for the purpose of attaining the above-mentioned object while investigating methods of surface treatment, and have found that, when a polyethylene terephthalate substrate is processed according to a special method prior to treatment thereof with a fluoropolymer, then the interlayer adhesiveness of the resulting sheet after wet heat aging can be bettered, and have completed the present invention.

Specifically, as the concrete means for solving the above-mentioned problems, the invention includes the following:

[1] A solar cell protective sheet comprising a polyethylene terephthalate-containing substrate that has been surface-treated through flame treatment with a silane compound-introduced flame or through atmospheric-pressure plasma treatment, and having, on the treated surface of the substrate, a coating layer that contains a fluoropolymer.
[2] The solar cell protective sheet according to [1], wherein the coating layer contains a crosslinked structure derived from at least one of a carbodiimide compound-type crosslinking agent and an oxazoline compound-type crosslinking agent.
[3] The solar cell protective sheet according to [1] or [2], wherein the coating layer contains at least one filler.
[4] The solar cell protective sheet according to any one of [1] to [3], of which the elongation at break after stored under the condition at 120° C. and a relative humidity of 100% for 50 hours is at least 50% of the elongation at break thereof before storage.
[5] The solar cell protective sheet according to any one of [1] to [4], of which the thermal shrinkage before and after storage at 150° C. for 30 minutes is from 0 to 0.5%.
[6] The solar cell protective sheet according to any one of [1] to [5], wherein the treated surface of the substrate and the coating layer are kept in direct contact with each other without any adhesive or sticking agent therebetween.
[7] The solar cell protective sheet according to any one of [1] to [6], wherein the thickness of the coating layer is from 0.5 to 15 μm.
[8] The solar cell protective sheet according to any one of [1] to [7], wherein the coating layer is an outermost layer.
[9] The solar cell protective sheet according to any one of [1] to [8], wherein the substrate is used on the sealant side of the cell-side substrate of a solar cell element sealed up with a sealant.
[10] A method for producing a solar cell protective sheet, comprising processing at least one surface of a polyethylene terephthalate substrate through flame treatment with a silane compound kept introduced into a flame or through plasma treatment under atmospheric pressure, and coating the treated surface of the substrate with a fluoropolymer-containing, coating layer composition.
[11] The method for producing a solar cell protective sheet according to [10], wherein the coating layer composition contains at least one of a carbodiimide compound-type crosslinking agent and an oxazoline compound-type crosslinking agent.
[12] The method for producing a solar cell protective sheet according to [10] or [11], wherein the coating layer composition contains at least one filler.
[13] A solar cell protective sheet produced according to the solar cell protective sheet production method of any one of [10] to [12].
[14] A back sheet for solar cells, containing the solar cell protective sheet of any one of [1] to [9] and [13].
[15] A solar cell module containing the solar cell protective sheet of any one of [1] to [9] and [13].
[16] The solar cell module according to [15], which comprises a solar cell element and a cell-side substrate containing a sealant for sealing the solar cell element, and wherein the sealant of the cell-side substrate is kept in contact with the substrate of the solar cell protective sheet.
[17] The solar cell module according to [15] or [16], wherein the coating layer of the solar cell protective sheet is arranged as the outermost layer.

According to the invention, there are provided a solar cell protective sheet excellent in interlayer adhesiveness after wet heat aging and its production method, as well as a back sheet for solar cells and a solar cell module having long-term durability.

### BRIEF DESCRIPTION OF DRAWINGS

FIG. 1 is a schematic cross-sectional view showing a configuration example of a solar cell module. In FIG. 1, 10 is solar cell module, 12 is back sheet (solar cell protective sheet of the invention), 14 is coating layer (fluoropolymer layer), 16 is PET support, 18 is reflection layer, 20 is solar cell element, 22 is sealant, and 24 is transparent front substrate.

### MODE FOR CARRYING OUT THE INVENTION

The solar cell protective sheet and its production method of the invention, as well as the back sheet for solar cells and the solar cell module using the protective sheet of the invention are described in detail hereinunder.

The description of the constitutive elements of the invention given hereinunder is for some typical embodiments of the invention, to which, however, the invention should not be limited. In this description, the numerical range expressed by the wording “a number to another number” means the range that falls between the former number indicating the lower limit of the range and the latter number indicating the upper limit thereof.

### [Solar Cell Protective Sheet]

The solar cell protective sheet of the invention (hereinafter this may be referred to as the sheet of the invention or the film of the invention) comprises a polyethylene terephthalate-containing substrate that has been surface-treated through flame treatment with a silane compound-introduced flame or through atmospheric-pressure plasma treatment, and has, on the treated surface of the substrate, a coating layer that contains a fluoropolymer.

The solar cell protective sheet of the invention is described below in order of the substrate, the coating layer, the layer configuration and the characteristics of the solar cell protective sheet.

### <Substrate>

The solar cell protective sheet of the invention comprises a polyethylene terephthalate-containing substrate that has been surface-treated through flame treatment with a silane compound-introduced flame or through atmospheric-pressure plasma treatment. The substrate is described below.

### (Type)

The substrate contains polyethylene terephthalate. The substrate may contain any other resin than polyethylene terephthalate, but preferably contains polyethylene terephthalate alone as the resin therein.

Preferably, the carboxyl group content of the polyethylene terephthalate in the substrate is at most 55 equivalents/ton, more preferably 35 equivalents/ton. When the carboxyl group content is at most 55 equivalents/ton, then the polymer secures hydrolysis resistance and the strength reduction in wet heat aging can be suppressed. Accordingly, there can be obtained a solar cell back sheet of which the elongation at break after stored under the condition of 120° C. and a relative humidity of 100% for 50 hours is at least 50% of the elongation at break before storage.

The lower limit of the carboxyl group content is preferably 2 equivalents/ton from the viewpoint of securing the adhesiveness between the substrate and the coating layer formed on the substrate.

The carboxyl group content in the polyester can be controlled by the type of the polymerization catalyst to be used, the condition for film formation (temperature and time for film formation), and the mode of solid-phase polymerization.

### (Surface Treatment)

The substrate is surface-treated through (1) flame treatment with a silane compound-introduced flame or (2) atmospheric-pressure plasma treatment. According to the surface treatment method, the interlayer adhesiveness after wet heat aging of the treated surface of the polyethylene terephthalate substrate to the fluoropolymer-containing coating layer formed thereon can be enhanced. Heretofore, no one has known a case of coating the surface of a PET resin, which has been surface-treated with a surface treatment method of (1) flame treatment using a silane compound-introduced flame or (2) atmospheric-pressure plasma treatment, with a fluoropolymer. The present inventors have found that, when the surface treatment method is employed, then the adhesiveness in aging under wet heat conditions between the PET resin substrate layer and the fluoropolymer coating layer can be significantly enhanced.

The surface treatment is given to at least the surface of the substrate on the side thereof to be coated with the coating layer. In case where the coating layer is formed on one side of the substrate, the surface treatment may be given to the one surface alone of the substrate, or may be given to both surfaces of the substrate. For example, in case where any other functional layer to be described below is formed by coating on the solar cell protective sheet of the invention, it is desirable that the surface treatment is given to both surfaces of the substrate. The details of the surface treatment are described in the section of the solar cell protective sheet production method of the invention to be given hereinunder.

### (Other Additives)

Preferably, the substrate film is formed using a titanium compound as the catalyst. The amount of the titanium compound to be used as the catalyst may be small as compared with that of any other catalysts (Sb, Ge, Al), and therefore spherical crystals can be prevented from forming around the nuclei of the catalyst. The details of the titanium compound are described in the section of the film production method of the invention to be given hereinunder.

The substrate film may further contain any additives such as light stabilizer, antioxidant, etc.

In addition, the substrate film may further contain still other additives, for example, lubricant (fine particles), colorant, heat stabilizer, nucleating agent (crystallization agent), flame retardant, etc.

### (Thickness)

Preferably, the thickness of the substrate is from 30 μm to 500 μm, more preferably from 40 μm to 400 μm, even more preferably from 45 μm to 360 μm.

Of the above, in case where the solar cell protective sheet of the invention is used, not laminated with any other resin film, it is desirable that the thickness of the substrate is large, more preferably falling within a range of from 30 to 500 μm, even more preferably from 40 to 400 μm, still more preferably from 45 to 360 μm.

It may be desirable to thicken the substrate; however, when the substrate is too thick, then the water content of the film may increase, directly resulting in reduction in the hydrolysis resistance of the substrate. Accordingly, when a conventional known substrate is merely thickened, then the hydrolysis resistance thereof would lower and the intended long-term durability could not be obtained. As opposed to this, in the solar cell protective sheet of the invention, the substrate is, after surface-treated in the specific manner as above, coated with a fluoropolymer, and therefore even through the substrate is thickened, the protective sheet can still secure good elongation at break after wet heat aging.

### <Coating Layer>

The solar cell protective sheet of the invention has, on the treated surface of the substrate therein, a fluoropolymer-containing coating layer (hereinafter this may be referred to as a fluoropolymer coating layer). The coating layer is described below.

### (Fluoropolymer)

The fluoropolymer is a polymer having a recurring unit represented by —(CFX¹—CX²X³)— (wherein X¹, X² and X³ each represent a hydrogen atom, a fluorine atom, a chlorine atom, or a perfluoroalkyl group having from 1 to 3 carbon atoms(.

The fluoropolymer-containing coating layer is a layer comprising a fluoropolymer (fluorine-containing polymer) as the main binder therein and formed by coating. The main binder is a binder of which the content in the fluoropolymer coating layer is the largest.

Concrete examples of the fluoropolymer include polytetrafluoroethylene (hereinafter this may be expressed as PTFE), polyvinyl fluoride (hereinafter this may be expressed as PVF), polyvinylidene fluoride (hereinafter this may be expressed as PVDF), polychlorotrifluoroethylene (hereinafter this may be expressed as PCTFE), polytetrafluoropropylene (hereinafter this may be expressed as HFP), etc.

Of those, preferred is use of PTFE or PCTFE.

The polymer may be a homopolymer produced through polymerization of a single monomer, or a copolymer produced through copolymerization of two or more different types of monomers. As its examples, there are mentioned a copolymer produced through copolymerization of tetrafluoroethylene and tetrafluoropropylene (abbreviated as P(TFE/HFP)), a copolymer produced through copolymerization of tetrafluoroethylene and vinylidene fluoride (abbreviated as P(TFE/VDF)), etc.

Further, the polymer for use for the fluoropolymer-containing coating layer may also be a copolymer produced through copolymerization of a fluoromonomer represented by —(CFX¹—CX²X³)— and any other monomer. As its examples, there are mentioned a copolymer of tetrafluoroethylene and ethylene (abbreviated as P(TFE/E)), a copolymer of tetrafluoroethylene and propylene (abbreviated as P(TFE/P)), a copolymer of tetrafluoroethylene and vinyl ether (abbreviated as P(TFE/VE)), a copolymer of tetrafluoroethylene and perfluorovinyl ether (abbreviated as P(TFE/FVE)), a copolymer of chlorotrifluoroethylene and vinyl ether (abbreviated as P(CTFE/VE)), a copolymer of chlorotrifluoroethylene and perfluorovinyl ether (abbreviated as P(CTFE/FVE)), etc.

Of those homopolymers and copolymers, preferred is use of P(TFE/E) or P(CTFE/VE).

The fluoropolymer maybe one to be dissolved in an organic solvent or may be in the form of fine particles to be dispersed in water. From the viewpoint of low environmental load, preferred is the latter. Aqueous dispersions of fluoropolymer are described, for example, in JP-A 2003-231722, 2002-20409, 9-194538.

The fluoropolymer may be a commercially-available one, and for example, Obbligato SW0011F (fluorobinder, by AGC Coat-Tech), Daikin Industry's Zeffle and the like are preferably used in the invention.

As the binder for the fluoropolymer-containing coating layer, the fluoropolymer may be used singly or two or more different types of such fluoropolymers may also be used as combined. In addition, within a range not more than 50% by mass of all binders, any other resin than fluoropolymer, such as acrylic resin, polyester resin, polyurethane resin, polyolefin resin, silicone resin and the like may be used along with the fluoropolymer. However, when the amount of the other resin than fluoropolymer is more than 50% by mass in the coating layer of the back sheet, then the weather resistance of the back sheet may worsen.

### (Crosslinking Agent)

The fluoropolymer-containing coating layer may contain various additives, and preferably contains a crosslinking agent, a surfactant and a filler.

As the crosslinking agent preferred for use in the fluoropolymer-containing coating layer, there are mentioned epoxy-type, isocyanate-type, melamine-type, carbodiimide-type, oxazoline-type and the like crosslinking agents. From the viewpoint of securing the adhesiveness after wet heat aging, especially preferred is use of a carbodiimide-type crosslinking agent or an oxazoline-type crosslinking agent among the above. Using the crosslinking agent of the type synergistically enhances the adhesiveness after wet heat aging of the coating layer to the substrate that has been surface-treated through flame treatment with a silane compound-added flame or through atmospheric plasma treatment. Specifically in the invention, it is desirable that the coating layer contains a crosslinked structure derived from at least one of a carbodiimide compound-type crosslinking agent and an oxazoline compound-type crosslinking agent.

Specific examples of the oxazoline-type crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylenebis(2-oxazoline), 2,2′-ethylenebis(2-oxazoline), 2,2′-trimethylenebis(2-oxazoline), 2,2′-tetramethylenebis(2-oxazoline), 2,2′-hexamethylenebis(2-oxazoline), 2,2′-octamethylenebis(2-oxazoline), 2,2′-ethylenebis(4,4′-dimethyl-2-oxazoline), 2,2′-p-phenylenebis(2-oxazoline), 2,2′-m-phenylenebis(2-oxazoline), 2,2′-m-phenylenebis(4,4′-dimethyl-2-oxazoline), bis(2-oxazolinylcyclohexane) sulfide, bis(2-oxazolinylnorbornane) sulfide, etc. Further, (co)polymers of these compounds are preferably used here.

As the oxazoline-type crosslinking agent, also usable are Epocross K2010E, K2020E, K2030E, WS500, WS700 (all by Nippon Shokubai), etc.

Specific examples of the carbodiimide-type crosslinking agent include Carbodilite V-02-L2 (by Nisshinbo), and the following compounds: Carbodilite SV-02, Carbodilite V-02, Carbodilite V-04, Carbodilite E-01, Carbodilite E-02 (all by Nisshinbo).

Preferably, the amount of the crosslinking agent to be added is from 0.5 to 25% by mass of the binder in the coating layer, more preferably from 2 to 20% by mass. When the amount of the crosslinking agent added is at least 0.5% by mass, then the agent exhibits a sufficient crosslinking effect while securing the strength and the adhesiveness of the coating layer; and when at most 25% by mass, then the pot life of the coating liquid can be kept long.

### (Surfactant)

The surfactant usable in the fluoropolymer-containing coating layer may be any known surfactant including anionic and nonionic surfactants. In case where a surfactant is added to the layer, the amount thereof to be added is preferably from 0.1 to 15 mg/m², more preferably from 0.5 to 5 mg/m². When the amount of the surfactant added is at least 0.1 mg/m², then a good coating layer can be formed with no crawling; and when at most 15 mg/m², then the adhesiveness of the coating layer can be good.

### (Filler)

Preferably, the fluoropolymer-containing coating liquid contains at least one filler. The filler may be any known filler such as colloidal silica, titanium dioxide, etc. The amount of the filler to be added is preferably at most 20% by mass of the binder in the coating layer, more preferably at most 15% by mass. When the amount of the filler is at most 20% by mass, then the surface condition of the coating layer can be good, and the adhesiveness thereof to the PET substrate may be bettered.

### (Thickness)

Preferably, the thickness of the fluoropolymer-containing coating layer is from 0.5 to 15 μm, more preferably from 0.8 to 12 μm, even more preferably from 1.0 to 10 μm. When the thickness of the coating layer is at least 0.5 μm, then the coating layer can sufficiently exhibit the durability (weather resistance) as the polymer sheet, especially as the outermost layer of the solar cell back sheet; but when more than 15 μm, then the adhesiveness of the coating layer to the substrate would be insufficient.

### (Position)

In the solar cell protective sheet of the invention, any other layer may be laminated on the fluoropolymer-containing coating layer; however, from the viewpoint of enhancing the durability of the sheet, and reducing the weight, the thickness and the cost thereof, it is desirable that the coating layer is the outermost layer of the sheet.

### <Layer Configuration>

The solar cell protective sheet of the invention may be composed of the substrate and the fluoropolymer-containing coating layer alone, but may be a laminate having any other layer. In the latter case, the laminate may be one having any other polyester film and any other resin film, or may be one having any other coating layer.

Preferably, the solar cell protective sheet of the invention is such that the treated surface of the substrate is in direct contact with the coating layer without any adhesive or sticking agent therebetween. In the case, the solar cell protective sheet of the invention may have an undercoat layer between the treated surface of the substrate and the coating layer; however, in the solar cell protective sheet of the invention, the treated surface of the substrate is preferably in direct contact with the coating layer. The polymer sheet of the invention may be composed of the substrate and the coating layer alone, or may have any other layer to be selected in a desired manner (for example, colorant layer, undercoat layer, easy-adhesion layer, etc.) on the surface of the substrate or on the surface of the coating layer, or on the surfaces of the two.

The solar cell protective sheet of the invention may have any other functional layer to be selected in a desired manner, on the surface of the substrate or on the surface of the fluoropolymer coating layer, or on the surfaces of the two. The number of the additional layer may be one or may also be two or more.

Of the functional layer, preferably, the film of the invention is in an embodiment having a colorant layer (preferably a white layer (reflection layer)) laminated on the substrate, or preferably in an embodiment having an easy-adhesion layer and a white layer (reflection layer) laminated on one surface of the substrate, or preferably in an embodiment having an easy-adhesion layer and a white layer (reflection layer) laminated on one surface of the substrate by coating thereon. Of those, preferred is the embodiment of providing a colorant layer on the side of the substrate opposite to the side thereof coated with the coating layer. Preferably, the functional layer is formed on the side of the solar cell protective sheet of the invention to be stuck to the sealant that seals the solar cell element to be protected with the sheet. Specifically, it is desirable that the functional layer is formed on the surface of the substrate of the solar cell protective sheet of the invention, on which the coating layer is not formed, and preferably, the substrate is on the side of the sealant for the cell-side substrate of the solar cell element sealed up with the sealant.

Preferably, in the solar cell protective sheet of the invention, the coating layer is the outermost layer, or that is, the fluoropolymer-containing coating layer is preferably so arranged as to be the outermost layer when the sheet is incorporated in a solar cell module, from the viewpoint of enhancing the weather resistance of the sheet.

### <Characteristics of Solar Cell Protective Sheet>

### (Thermal Shrinkage)

Preferably, the thermal shrinkage of the solar cell protective sheet of the invention is from 0 to 0.5%.

More preferably, the thermal shrinkage is from 0.05% to 0.5%, even more preferably from 0.1 to 0.45%, still more preferably from 0.15% to 0.4%. The thermal shrinkage as referred to herein indicates the mean value in MD (machine direction, film-traveling direction) and TD (transverse direction, direction perpendicular to the film-traveling direction) of the data measured before and after storage at 150° C. for 30 minutes.

When the thermal shrinkage is not more than the upper limit of the range, then the solar cell protective sheet hardly delaminates by shrinkage. On the other hand, when the shrinkage is at least 0.05%, then it is desirable from the viewpoint that the sheet would have few wrinkles owing to dimensional change (sagging) through thermal expansion during heat treatment.

### (Retention of Elongation at Break)

Preferably, the elongation at break of the solar cell protective sheet of the invention after heat treatment at 120° C. and at a relative humidity of 100% for 50 hours (retention of elongation at break thereof) is at least 50% of the elongation at break of the sheet before storage.

More preferably, the retention of elongation at break is at least 60%, even more preferably at least 70%, still more preferably at least 75%.

### [Production Method for Solar Cell Protective Sheet]

The production method for the solar cell protective sheet of the invention (hereinafter this may be referred to as the film production method of the invention) comprises a step of processing at least one surface of a polyethylene terephthalate substrate through flame treatment with a silane compound kept introduced into a flame or through plasma treatment under atmospheric pressure, and a step of coating the treated surface of the substrate with a fluoropolymer-containing, coating layer composition.

The production method of the invention is described below.

### (Preparation of Starting PET Resin)

Preferably, in the film production method of the invention, a polyester resin having an intrinsic viscosity IV of from 0.74 to 0.91 dL/g is used for melt film formation.

The starting PET resin of which IV falls within the range may be obtained by synthesis and polymerization or may be a commercially-available one.

For controlling the IV value as above, the polymerization time in solid-phase polymerization for the polymer may be controlled and/or the polymer may be produced through solid-phase polymerization.

Preferably, the film production method of the invention includes an esterification step of esterification and/or interesterification to produce a polyester resin having an intrinsic viscosity VI of from 0.74 to 0.91 dL/g.

—Esterification Step—The method of the invention may include an esterification step of forming a polyester through esterification and polycondensation. The esterification step may comprise (a) esterification and (b) polycondensation of the esterified product formed through the esterification.

### (a) Esterification

Preferably, the amount of the aliphatic diol (ethylene glycol) to be used is within a range of from 1.015 to 1.50 mols relative to one mol of an aromatic dicarboxylic acid (terephthalic acid) and optionally its ester derivative. The amount to be used is more preferably from 1.02 to 1.30 mols, even more preferably from 1.025 to 1.10 mols. When the amount to be used is at least 1.015 mols, then the esterification may go on well; and when at most 1.50 mols, for example, ethylene glycol may be prevented from being dimerized to give a side product, diethylene glycol, and consequently, the resulting polyester can maintain good melting point and glass transition temperature and can have may other good properties of crystallinity, heat resistance, hydrolysis resistance, weather resistance, etc.

Preferably, PET contains terephthalic acid and ethylene glycol in an amount of at least 90 mol %, more preferably at least 95 mol %, even more preferably at least 98 mol %.

PETs may have different properties depending on the catalyst used in producing them, as mentioned below. Preferred are PETs produced through polymerization by the use of one or more selected from a germanium (Ge) catalyst, an antimony (Sb) catalyst, an aluminium (Al) catalyst, and a titanium (Ti) catalyst, and more preferred are those produced with a Ti catalyst.

Any reaction catalyst heretofore known in the art can be used in esterification and/or interesterification. The reaction catalyst includes alkali metal compounds, alkaline earth metal compounds, zinc compounds, lead compounds, manganese compounds, cobalt compounds, aluminium compounds, antinomy compounds, titanium compounds, germanium compounds, phosphorus compounds, etc. In general, in any stage before completion of the polyester production method, it is desirable to add, as a polymerization catalyst, any of an antimony compound, a germanium compound or a titanium compound. In such a method where, for example, a germanium compound is used, it is desirable that the germanium compound powder is added to the reaction system directly as it is.

Preferably, the production method for the film of the invention includes a step of preparing the above-mentioned polyester resin to be subjected to casting film formation, through esterification with a Ti catalyst.

The film containing the polyester resin that has been esterified by the use of a Ti catalyst is preferred as hardly undergoing reduction in weather resistance thereof. Though not adhering to any theory, the reason will be as follows: The reduction in the weather resistance of a weather-resistant polyester film depends on hydrolysis of polyester in some degree. The esterification catalyst may promote hydrolysis that is counter-reaction to esterification, however, the Ti catalyst poorly acts for the counter-reaction, hydrolysis. Consequently, even though the esterification reaction may remain in some degree in the formed film, the polyester resin esterified by the use of such a Ti catalyst could keep relatively high the weather resistance thereof, as compared with any other polyester resin esterified by the use of any other catalyst.

The Ti catalyst includes oxides, hydroxides, alkoxides, carboxylate salts, carbonate salts, oxalate salts, organic chelate titanium complexes, halides, etc. Two or more different types of titanium compounds may be used as the Ti catalyst within the range not detracting from the advantages of the invention.

Examples of the Ti catalyst include titanium alkoxides such as tetra-n-propyl titanate, tetra-1-propyl titanate, tetra-n-butyl titanate, tetra-n-butyl titanate tetramer, tetra-t-butyl titanate, tetracyclohexyl titanate, tetraphenyl titanate, tetrabenzyl titanate, etc.; titanium oxides to be prepared through hydrolysis of titanium alkoxides; titanium-silicon or zirconium composite oxides to be prepared through hydrolysis of mixture of titanium alkoxide and silicon alkoxide or zirconium alkoxide; titanium acetate, titanium oxalate, titanium potassium oxalate, titanium sodium oxalate, potassium titanate, sodium titanate, titanic acid-aluminium hydroxide mixture, titanium chloride, titanium chloride-aluminium chloride mixture, titanium acetylacetonate, organic chelate titanium complexes with an organic acid as the ligand therein, etc.

Of the above-mentioned Ti catalysts, preferred for use herein is at least one organic chelate titanium complex with an organic acid as the ligand therein. The organic acid includes, for example, citric acid, lactic acid, trimellitic acid, malic acid, etc. Above all, preferred are organic chelate complexes with citric acid or a citrate salt as the ligand therein.

In case where a chelate titanium complex with citric acid as the ligand therein is used, few impurities such as fine particles generate and, as compared with any other titanium compound, the catalyst has higher polymerization activity and the color of the obtained polyester resin maybe good. Further, even when a citric acid-chelated titanium complex is used but when the complex is added during the stage of esterification, the polymerization activity of the complex is better and the color of the obtained polyester resin may also be better and, in addition, the amount of the terminal carboxyl group in the polyester resin obtained may be small, as compared with the case of adding it after esterification. The reason would be because the titanium catalyst additionally has a catalytic effect for esterification, and therefore, when it is added during esterification, the oligomer acid value may be low after the esterification so that the subsequent polycondensation may be attained more efficiently, and in addition, the complex with citric acid as the ligand therein has higher hydrolysis resistance than that of titanium alkoxide and the like, and therefore during the step of esterification, the complex would not hydrolysis and could therefore effectively function as the catalyst for esterification and polycondensation while maintaining its intrinsic activity as it is.

In addition, in general, it is known that when the amount of the terminal carboxyl group in the polyester is larger, then the hydrolysis resistance of the polyester is poorer; however, according to the addition method of the invention, the amount of the terminal carboxyl group could reduce and the hydrolysis resistance of the polyester could be expected to be higher.

The citric acid-chelated titanium complex is easily available as a commercial product, for example, as VERTEC AC-420 by Johnson Massey.

For production of such Ti-assisted polyesters using the Ti compound of the type, for example, the methods described in JP-B 8-30119, Japanese Patent 2543624, 3335683, 3717380, 3897756, 3962226, 3979866, 39996871, 4000867, 4053837, 4127119, 4134710, 4159154, 4269704, 4313538, JP-A 2005-340616, 2005-239940, 2004-319444, 2007-204538, Japanese Patent 3436268, 3780137 and others are applicable.

In the invention, preferably, the production process includes at least an esterification step, in which an aromatic dicarboxylic acid and an aliphatic diol are polymerized in the presence of a catalyst containing a titanium compound, in which at least one titanium compound is an organic chelate titanium complex with an organic acid as the ligand therein, and in which the organic chelate titanium complex, a magnesium compound and a pentavalent phosphate ester not having an aromatic ring as the substituent are added to the system in that order. For this case, also preferred is an embodiment which includes, in addition to the esterification step, a polycondensation step of forming a polycondensate through polycondensation of the esterified reaction product produced in the esterification step, thereby producing a film according to the polyester resin production step of this embodiment. The polycondensation step is described hereinunder.

In this case, during the esterification step, a magnesium compound may be added to the system where an organic chelate titanium compounds exists as the titanium compound, and then a specific pentavalent phosphorus compound may be added in that order, whereby the reaction activity of the titanium catalyst can be kept high and the electrostatic property of magnesium can be imparted to the system and, in addition, the decomposition reaction can be effectively inhibited during polycondensation; and as a result, a polyester resin with little discoloration can be obtained and the obtained polyester resin can have high electrostatic characteristics and can be prevented from yellowing when exposed to high-temperature environments.

Accordingly, there can be provided a polyester resin which discolors little in polymerization and also in subsequent casting film formation, which, as compared with the polyester resin produced by the use of a conventional antimony (Sb) catalyst, yellows little, and which, as compared with the polyester resin produced by the use of a germanium catalyst having relatively high transparency, has color and transparency comparable with those of the polyester resin produced by the use of such a germanium catalyst, and additionally has excellent heat resistance. In addition, not using a cobalt compound or any other coloration-regulating agent such as a dye or the like, a PET resin that yellows little can be obtained.

The polyester resin is applicable to use that requires high transparency (for example, for optical films, industrial lithography materials, etc.) and does not require an expensive germanium catalyst, and therefore contributes toward significant cost reduction. In addition, the polyester resin is prevented from contamination with catalyst-derived impurities, which often occurs in a Sb catalyst-assisted system, and accordingly, the polyester resin is free from troubles in the process of film formation and from problems of poor quality of film products, and therefore can contribute toward cost reduction through increase in the production yield.

In the above, in case where the aromatic dicarboxylic acid and the aliphatic diol are mixed with a catalyst that contains a titanium compound of an organic chelate titanium complex prior to adding a magnesium compound and a phosphorus compound thereto, the organic chelate titanium complex and others have high catalytic activity for esterification, and therefore facilitate esterification. In this case, a titanium compound may be added to a mixture of a dicarboxylic acid component and a diol component. Alternatively, after a dicarboxylic acid component (or a diol component) is mixed with a titanium compound, the resulting mixture may be added to a diol component (or a dicarboxylic acid component). A dicarboxylic acid component, a diol component and a titanium compound may be mixed all at a time. The mode of mixing them is not specifically defined, for which is employable any known method.

In esterification, preferably, a titanium compound of an organic chelate titanium complex, and as additives, a magnesium compound and a pentavalent phosphorus compound are added to the system in that order. In this case, in the presence of an organic chelate titanium complex, the esterification is promoted and thereafter a magnesium compound is added to the system prior to adding a phosphorus compound.

As the pentavalent phosphorus compound, herein usable is at least one pentavalent phosphate ester not having an aromatic ring as the substituent. The pentavalent phosphate ester includes, for example, trimethyl phosphate, triethylphosphate, tri-n-butyl phosphate, trioctyl phosphate, tris(triethylene glycol) phosphate, methylphosphoric acid, ethylphosphoric acid, isopropylphosphoric acid, butylphosphoric acid, monobutyl phosphate, dibutyl phosphate, dioctyl phosphate, triethylene glycol phosphoric acid, etc.

Of pentavalent phosphate esters, preferred are phosphate esters having, as the substituent, a lower alkyl group with at least 2 carbon atoms [(OR)₃—P═O, where R represents an alkyl group having 1 or 2 carbon atoms], and concretely, trimethyl phosphate and triethyl phosphate are more preferred.

In particular, in case where a chelate titanium complex with citric acid or its salt as the ligand thereof is used as the titanium compound serving as a catalyst, pentavalent phosphate esters are better than trivalent phosphate esters in point of the polymerization activity thereof and the color of the polyester to be obtained. In particular, in an embodiment where a pentavalent phosphate ester having at most 2 carbon atoms is added, the balance among the polymerization activity of the catalyst, and the color and the heat resistance of the obtained polyester can be especially bettered.

The added magnesium compound enhances the static charge applicability. In this case, discoloration may occur, but in the invention, the discoloration can be retarded and a polymer excellent in color and heat resistance can be obtained.

The magnesium compound includes, for example, magnesium oxide, magnesium hydroxide, magnesium alkoxide, as well as magnesium salts such as magnesium acetate, magnesium carbonate, etc. Above all, most preferred is magnesium acetate from the viewpoint of the solubility thereof in ethylene glycol.

Here is mentioned one preferred embodiment, in which, before the esterification is finished, a chelate titanium complex having a ligand of citric acid or a citrate salt is added in an amount of from 1 ppm to 30 ppm to an aromatic dicarboxylic acid or an aliphatic diol, then in the presence of the chelate titanium complex, a magnesium salt of a weak acid is added in an amount of from 60 ppm to 90 ppm (more preferably in an amount of from 70 ppm to 80 ppm), and after the addition, a pentavalent phosphate ester not having an aromatic ring as the substituent is added in an amount of from 60 ppm to 80 ppm (more preferably in an amount of from 65 ppm to 75 ppm).

The esterification can be attained in a multistage apparatus in which at least two reactors are connected in series, under the condition under which ethylene glycol could be kept under reflux, while water or alcohol formed through the reaction are removed out of the reaction system.

A slurry of a dicarboxylic acid and a diol may be prepared and this may be continuously introduced into the esterification system.

The esterification may be attained in one stage or in multiple stages.

### (b) Polycondensation

The esterified product produced through the esterification is polycondensed to give a polycondensation product. The polycondensation may be attained in one stage or in multiple stages.

The esterified product such as oligomer and the like produced in the esterification is subsequently polycondensed. Preferably, the polycondensation is attained by introducing the esterified product into a multistage polycondensation reaction system.

For example, a preferred embodiment of the polycondensation condition in a three-stage reactor system is as follows: In the first reactor, the reaction temperature is from 255 to 280° C., preferably from 265 to 275° C., and the pressure is from 13.3×10⁻³ to 1.3×10⁻³ MPa (100 to 10 Torr), more preferably from 6.67×10⁻³ to 2.67×10⁻³ MPa (50 to 20 Torr); in the second reactor, the reaction temperature is from 265 to 285° C., preferably from 270 to 280° C., and the pressure is from 2.67×10⁻³ to 1.33×10⁻⁴ MPa (20 to 1 Torr), more preferably from 1.33×10⁻³ to 4.0×10⁻⁴ MPa (10 to 3 Torr); in the third reactor in the final reactor system, the reaction temperature is from 270 to 290° C., preferably from 275 to 285° C., and the pressure is from 1.33×10⁻³ to 1.33×10⁻⁵ MPa(10 to 0.1 Torr), more preferably from 6.67×10⁻⁴ to 6.67×10⁻⁵ MPa (5 to 0.5 Torr).

Elements of Ti, Mg and P may be determined through high-resolution inductively-coupled plasma mass spectrometry (HR-ICP-MS; SII Nanotechnology's AttoM) in which the elements in PET are quantified. From the found data, the content of each element [ppm] may be derived through computation.

### —Solid-Phase Polymerization Step—

A polyester that constitutes a substrate may be produced through solid-phase polymerization after polymerization. Accordingly, the preferred content of carboxyl group can be attained. The method of solid-phase polymerization includes a step of heat-treating the polyester after polymerization at from 170° C. to 240° C. or so for 5 to 100 hours or so in a nitrogen atmosphere or in vacuum, and therefore a degree of polymerization is increased. Concretely, in the solid-phase polymerization, the methods described in Japanese Patent 2621563, 3121876, 3136774, 3603585, 3616522, 3617340, 3680523, 3717392, 4167159 and others are applicable.

For the solid-phase polymerization, it is desirable that the polyester produced according to the above-mentioned esterification or a commercially-available polyester is pelletized into small pellets and these are processed for solid-phase polymerization.

The preferred solid-phase polymerization temperature is from 190 to 230° C., more preferably from 200° C. to 220° C., even more preferably from 205° C. to 215° C.

The preferred solid-phase polymerization time is from 10 hours to 80 hours, more preferably from 15 hours to 50 hours, even more preferably from 20 hours to 30 hours.

The heat treatment is attained preferably in a low-oxygen atmosphere, for example, preferably in a nitrogen atmosphere or in vacuum. Further, a polyalcohol (ethylene glycol or the like) may be added to the system in an amount of from 1 ppm to 1%

The solid-phase polymerization may be attained in a batch mode (in which resin is put into a container and stirred under heat for a predetermined period of time), or in a continuous mode (in which resin is put into a heated cylinder, and led to pass through it sequentially while kept heated under reflux therein for a predetermined period of time).

### (Formation of PET Film)

### (1) Melt Extrusion for Film Formation

Preferably, in the production method of the invention, the polyester after the solid-phase polymerization step is melt-kneaded and extruded out through a nozzle (extrusion die) to form a PET film.

Preferably, the PET obtained in the solid-phase polymerization step is dried. For example, the polyester is dried so as to have a residual water content of at most 100 ppm.

In the production method of the invention, the PET film may be melt by the use of an extruder. The melting temperature is preferable at 250° C. to 320° C., more preferably at 260° C. to 310° C., even more preferably at 270° C. to 300° C.

The extruder may be a single-screw one or a multi-screw one. From the viewpoint of preventing formation of terminal COOH through thermal decomposition, more preferably, the extruder is purged with nitrogen.

Before the PET resin is melt-extruded, inorganic fine particles may be added. The inorganic fine particles include, for example, silica, alumina, titania, zirconia, talc, calcium carbonate, kaolin, layered mica, barium sulfate, aluminium hydroxide, zinc oxide, barium sulfate, calcium phosphate, etc. Of those, preferred is calcium phosphate which is excellent in lubricity and has good adhesiveness to resin and therefore hardly peels off in long-term use.

In case where calcium phosphate is added, its amount to be added is preferably from 20 to 500 ppm in terms of ratio by weight to the PET resin, more preferably from 50 to 250 ppm, even more preferably from 70 to 200 ppm.

Preferably, the molten PET resin (resin melt) is extruded out through the extrusion die via a gear pump, a filter and the like. In this, the resin may be extruded as a single layer or as a multilayer structure.

In case where the molten resin (melt) is discharged out (for example, extruded out through a die), preferably, the shear rate in discharging is controlled to fall within a preferred range. Preferably, the shear rate in extrusion is from 1 s⁻¹ to 300 s⁻¹, more preferably from 10 s⁻¹ to 200 s⁻¹, even more preferably from 30 s⁻¹ to 150 s⁻¹. Accordingly, for example, when the resin melt is extruded out through a die, there occurs a phenomenon of die swelling (that the melt swells in the thickness direction). Specifically, a stress is given to the melt in the thickness direction (in the normal direction of the film), and therefore the molecular movement in the thickness direction of the melt is thereby promoted and COOH group and OH group can be made to exist in the melt. When the shear rate is at least 1 s⁻¹, then COOH group and OH group can be fully stepped in the inside of the melt; and when at most 300 s⁻¹, then COOH group and OH group can be made to exist in the surface of the film.

After the molten resin (melt) is discharged out (for example, extruded out through a die), preferably, the air gap between the melt and the casting roll is so controlled that the relative humidity therein is from 5 to 60%, more preferably from 10 to 55%, even more preferably from 15 to 50%. By controlling the relative humidity in the air gap to fall within the above range, the hydrophobicity of air can be controlled and the degree of COOH group and OH group to step in the inside of the film from the film surface can be controlled.

Preferably, the extruded melt is cooled on a support and solidified to give a film thereon.

Not specifically defined, the support may be any chill roll generally used in ordinary casting film formation.

The temperature of the chill roll itself is preferably from 10° C. to 80° C., more preferably from 15° C. to 70° C., even more preferably from 20° C. to 60° C. Further, from the viewpoint of increasing the adhesiveness between the molten resin (melt) and the chill roll to thereby enhance the cooling efficiency, it is desirable that static electricity is previously applied to the chill roll before the melt is brought into contact with it.

The thickness of the solidified (but unstretched) molten resin (melt) that has been discharged out like a strip falls within a range of from 2600 μm to 6000 μm; and after stretched, the solidified melt gives a polyester film having a thickness of from 260 μm to 400 μm. The thickness of the solidified melt is preferably within a range of from 3100 μm to 6000 μm, more preferably from 3300 μm to 5000 μm, further preferably from 3500 μm to 4500 μm. When the thickness of the solidified but unstretched film is at most 6000 μm, the film hardly wrinkles during melt extrusion and is prevented from being uneven. Preferably, the thickness of the solidified but unstretched film is at least 2600 μm from the viewpoint of preventing adhesion unevenness of the film to the chill roll (cooling roll for solidification) to occur owing to poor toughness of the melt, and from the viewpoint of reducing film unevenness.

### (Stretching Step)

The production method of the invention may include a step of stretching the extruded film (unstretched film) produced after the above-mentioned film formation step. In the production method of the invention, preferably, the substrate is biaxially stretched from the viewpoint of the mechanical strength thereof.

### (Surface Treatment)

The production method of the invention includes a step of processing at least one surface of a polyethylene terephthalate substrate through flame treatment with a silane compound kept introduced into a flame or through plasma treatment under atmospheric pressure.

The surface treatment method is described below.

(1) Flame Treatment Using a Flame with a Silane Compound Introduced Thereinto

As the flame treatment using a flame with a silane compound introduced thereinto, there is mentioned silicification flame treatment, and above all, preferred is Itro treatment. The Itro treatment is a surface treatment method of forming a nano-level silicon oxide film on the surface of a subject to be coated, via an oxidation flame from a flame burner. Specifically, differing from conventional pretreatment of modifying the surface alone of a substrate (flame treatment, corona treatment, plasma treatment), the Itro treatment is surface treatment of positively adding an easy-adhesion substance to the surface of a substrate.

The type of the silane compound is not specifically defined, including, for example, an alkylsilane compound, an alkoxysilane compound, etc.

Preferred examples of the alkylsilane compound and the alkoxysilane compound include tetramethylsilane, tetraethylsilane, dimethyldichlorosilane, dimethyldiphenylsilane, diethyldichlorosilane, diethyldiphenylsilane, methyltrichlorosilane, methyltriphenylsilane, dimethyldiethylsilane, tetramethoxysilane, tetraethoxysilane, methyltrimethoxysilane, dimethyldimethoxysilane, phenyltrimethoxysilane, dichlorodimethoxysilane, dichlorodiethoxysilane, diphenyldimethoxysilane, diphenyldiethoxysilane, trichloromethoxysilane, trichloroethoxysilane, triphenylmethoxysilane, triphenylethoxysilane, etc. One alone or two or more of these compounds may be used here either singly or as combined.

More preferably, the silane compound has at least one of a nitrogen atom, a halogen atom, a vinyl group and an amino group in the molecule or at the end of the molecule thereof.

More concretely, preferred is at least one compound of hexamethyldisilazane (boiling point: 126° C.), vinyltrimethoxysilane (boiling point: 123° C.), vinyltriethoxysilane (boiling point: 161° C.), trifluoropropyltrimethoxysilane (boiling point: 144° C.), trifluoropropyltrichlorosilane (boiling point: 113 to 114° C.), 3-aminopropyltrimethoxysilane (boiling point: 215° C.), 3-aminopropyltriethoxysilane (boiling point: 217° C.), hexamethyldisiloxane (boiling point: 100 to 101° C.), and 3-chloropropyltrimethoxysilane (boiling point: 196° C.). The silane compound of the type is well miscible with a carrier gas and may form a granular material (silica layer) on the surface of a carbon compound to modify the surface more homogeneously, and in relation to the boiling point thereof, apart of the silane compound of the type can readily remain on the surface of a carbon compound, thereby capable of providing a more excellent adhesion power between the treated substrate and the fluoropolymer-containing coating layer.

Preferably, the mean molecular weight of the silane compound falls within a range of from 50 to 1000 as measured through mass spectrometry. More preferably, the mean molecular weight of the silane compound falls within a range of from 60 to 500 as measured through mass spectrometry, even more preferably within a range of from 70 to 200.

Also preferably, the flame temperature falls within a range of from 400 to 2500° C. More preferably, the flame temperature falls within a range of from 500 to 1800° C., even more preferably within a range of from 800 to 1200° C.

Also preferably, a burner is provided for forming a flame. The type of the burner is not specifically defined, and for example, usable here is any of a premixing burner, a diffusive burner, a partial premixing burner, a spray burner, an evaporation burner, a pulverized coal burner, etc.

Also preferably, any other heat source than a burner is provided. The type of the additional heat source is not specifically defined, and for example, preferred is at least one heating means selected from a group consisting of a laser, a halogen lamp, an IR lamp, a high-frequency coil, an induction heating apparatus, a hot air heater, and a ceramic heater. For example, using a laser, it is possible to spot-wise and extremely rapidly heat and thermally decompose a silane compound for surface treatment of a carbon compound.

Using a halogen lamp or an IR lamp, it is possible to thermally decompose a large quantity of a silane compound with an extremely uniform temperature distribution for efficient surface treatment of a carbon compound.

Using a high-frequency coil or an induction heating apparatus, it is possible to extremely rapidly heat and thermally decompose a silane compound for efficient surface treatment of a carbon compound.

Using a hot air heater or a ceramic heater enables treatment at a temperature higher than 2000° C. in various sizes of from a small-scale size to a large-scale size, thereby making it possible to thermally decompose a silane compound with ease for efficient surface treatment of a carbon compound.

As other preferred embodiments of flame treatment with a flame with a silane compound introduced thereinto, for example, employable are the methods described in WO2003/069017, WO2004/014989, and JP-A 2003-238710, 2007-039508 and 2008-050629.

### (2) Atmospheric Plasma Treatment

Atmospheric plasma treatment is a method of producing stable plasma discharge under atmospheric pressure through radio-frequency radiation.

The carrier gas in the atmospheric plasma treatment is preferably argon gas, helium gas or the like partly mixed with oxygen gas, and more preferred is air mixed with argon gas.

Preferably, the atmospheric plasma treatment is carried out under atmospheric pressure and therearound, or under a pressure of from 500 to 800 Torr or so, more preferably under a pressure of from 700 to 800 Torr.

The power source frequency for discharge is preferably from 1 to 100 kHz, more preferably from 1 to 10 kHz or so. When the power source frequency is at least 1 kHz, then stable discharge can be obtained favorably. On the contrary, when at most 100 kHz, any expensive apparatus is not needed and the process is favorable from the viewpoint of cost.

The discharge intensity in the atmospheric plasma treatment is not specifically defined, but in the invention, the discharge intensity is preferably from 50 W·min/m² to 500 W·min/m² or so. When the discharge intensity in the atmospheric plasma treatment is at most 500 W·min/m², arc discharge would not occur and stable atmospheric plasma treatment could be attained. When at least 50 W·min/m², sufficient surface treatment could be effected.

The treatment time is preferably from 0.05 to 100 seconds, more preferably from 0.5 to 30 seconds or so. When the treatment time is at least 0.05 seconds, then the adhesiveness could be sufficiently enhanced; but on the contrary, when at most 100 seconds, then there would hardly occur problems of deformation and discoloration of the support.

For the atmospheric plasma treatment, the method of generating plasma is not specifically defined. In the invention, for example, an apparatus of direct current glow discharge, high frequency discharge, microwave discharge or the like may be used for the treatment. Especially preferred is a method of using a discharge apparatus that uses high-frequency waves at 3.56 MHz.

Other preferred embodiments of atmospheric plasma treatment are described in, for example, Japanese patent 3835261, which may be employed here.

### (Formation and Drying of Coating Layer)

The production method for a polyester film of the invention includes a step of coating the treated surface of the substrate with a fluoropolymer-containing, coating layer composition. Preferably, the method includes a step of drying the coating layer in a drying zone.

The fluoropolymer-containing coating layer may be formed by applying a fluoropolymer-containing coating liquid to constitute the fluoropolymer-containing coating layer, onto the treated surface of the substrate, and drying the coating layer. After dried, the coating layer may be cured by heating or the like. The coating method and the solvent for the coating liquid are not specifically defined.

In the coating method, for example, usable is a gravure coater or a bar coater.

The solvent for the coating liquid may be water, or may be an organic solvent such as toluene, methyl ethyl ketone, etc. One alone or two or more different types of solvents may be used either singly or as combined. Preferably, a water-based coating liquid is prepared by dispersing the binder such as fluoropolymer or the like in water, and this is applied to the substrate. In this case, the proportion of water in the solvent is preferably at least 60% by mass, more preferably at least 80% by mass. When the content of water in the solvent to be contained in the coating liquid to form the coating layer is at least 60% by mass, then the environmental load could be favorably reduced.

The coating layer may be formed on one surface of both surfaces of the film of the invention.

The amount of the fluoropolymer to be in the coating layer is preferably from 0.5 g/m² to 15 g/m² as the binder amount therein, from the viewpoint of securing the weather resistance of the coating film, more preferably from 1 g/m² to 4 g/m², even more preferably from 1.5 g/m² to 2.5 g/m².

### (Production of Back Sheet for Solar Cells)

The film of the invention may be used as a transparent front substrate on the side of a solar cell module on which sunlight falls, or may be used as aback sheet for solar cells, but preferably, the film is used as a back sheet for solar cells.

The back sheet for solar cells of the invention contains the film of the invention. Further, the back sheet for solar cells of the invention may be composed to have, as provided thereon, at least one functional layer of an easy-adhesion layer that is easily adhesive to adherends, a UV absorbent layer, a light-reflecting white layer, etc.

Methods for laminating various functional layers on the substrate and on the coating layer in the case of using the film of the invention as a back sheet for solar cells are described below.

The back sheet for solar cells of the invention may be produced, for example, by providing a functional layer mentioned below on a monoaxially stretched and/or biaxially stretched film. For providing the functional layer, employable is any known coating technique of a roll coating method, a knife edge coating method, a gravure coating method, a curtain coating method or the like.

Before coating with the layer, the film may be surface-treated (flame treatment, corona treatment, plasma treatment, UV treatment or the like). Also preferably, the coating layer may be adhered to the film by using an adhesive.

### —Colorant Layer (Reflection Layer)—

A colorant layer may be arranged in the polyester film of the invention. The colorant layer is arranged in the polyester film while kept in contact with the surface of the film or while spaced from it via any other layer arranged therebetween, and the layer may contain a pigment and a binder.

The first function of the colorant layer is to reflect the light part of the incident light, which has not been used for power generation in a solar cell element but has reached the back sheet, so as to return back it to the solar cell element to thereby increase the power generation efficiency of the solar cell module. The second function is to enhance the decorative design of the outward appearance of a solar cell module when seen from its front side. In general, when a solar cell module is seen from its front side, the back sheet is seen around the solar cell element therein, but by providing a colorant layer on the back sheet in the module, the decorative design of the module can be bettered.

### (1) Pigment

The colorant layer in the invention may contain at least one pigment. Preferably, the amount of the pigment to be in the layer is from 2.5 to 8.5 g/m². More preferably, the pigment amount is from 4.5 to 7.5 g/m². When the pigment amount is at least 2.5 g/m², then the layer readily secures the necessary coloration and can control the light reflectivity and can further better the decorative design of the module. When the pigment content is at most 8.5 g/m², then the surface condition of the colorant layer can be kept better.

The pigment includes, for example, inorganic pigments such as titanium oxide, barium sulfate, silicon oxide, aluminium oxide, magnesium oxide, calcium carbonate, kaolin, talc, ultramarine, Prussian blue, carbon black, etc.; organic pigments such as phthalocyanine blue, phthalocyanine green, etc. Of those pigments, preferred are white pigments from the viewpoint that the colorant layer could act as a reflection layer that reflects the incident light thereto. For example, preferred are titanium oxide, barium sulfate, silicon oxide, aluminium oxide, magnesium oxide, calcium carbonate, kaolin, talc, etc.

The mean particle size of the pigment is preferably from 0.03 to 0.8 μm, more preferably from 0.15 to 0.5 μm or so. When the mean particle size falls within the range, then the light reflection efficiency of the particles may be improved.

In case where the colorant layer acts as a reflection layer that reflects the incoming sunlight, the amount of the pigment to be in the reflection layer may vary depending on the type and the mean particle size of the pigment to be used and therefore could not be indiscriminately defined. However, the amount is preferably from 1.5 to 15 g/m², more preferably from 3 to 10 g/m² or so. When the amount is at least 1.5 g/m², then the layer can readily secure the necessary reflectivity; and when at most 15 g/m², then the strength of the reflection layer can be kept further higher.

### (2) Binder

The colorant layer in the invention may contain at least one binder. The amount of the binder, if any, in the layer is preferably from 15 to 200% by mass of the pigment therein, more preferably from 17 to 100% by mass. When the amount of the binder is at least 15% by mass, then the strength of the colorant layer can be kept better; and when at most 200% by mass, the reflectivity and the decorative design of the layer may be improved.

The binder favorable for the colorant layer includes, for example, polyesters, polyurethanes, acrylic resins, polyolefins, etc. Above all, from the viewpoint of the durability thereof, acrylic resins and polyolefins are preferred for the binder. As the acrylic resin, also preferred is a composite resin of acryl and silicone. Preferred examples of the binder are mentioned below.

Examples of polyolefins include Chemipearl S-120, S-75N (both by Mitsui Chemical). Examples of acrylic resins include Jurymer ET-410, SEK-301 (both by Nihon Junyaku). Examples of composite resin of acryl and silicone include Ceranate WSA1060, WSA1070 (both by DIC), and H7620, H7630, H7650 (all by Asahi Kasei Chemicals).

### (3) Additive

The colorant layer in the invention may optionally contain a crosslinking agent, a surfactant, a filler and others, in addition to the binder and the pigment.

The crosslinking agent includes epoxy-type, isocyanate-type, melamine-type, carbodiimide-type, oxazoline-type and the like crosslinking agents. The amount of the crosslinking agent in the colorant layer is preferably from 5 to 50% by mass of the binder therein, more preferably from 10 to 40% by mass. When the amount of the crosslinking agent is at least 5% by mass, then the agent can exhibit good crosslinking effect and the strength and the adhesiveness of the colorant layer can be thereby kept high; and when at most 50% by mass, the pot life of the coating liquid for the layer can be kept long.

As the surfactant, any known surfactant such as anionic or nonionic surfactant can be used. The amount of the surfactant to be added is preferably from 0.1 to 15 mg/m², more preferably from 0.5 to 5 mg/m². When the amount of the surfactant is at least 0.1 mg/m², then the coating failure can be effectively prevented; and when at most 15 mg/m², the adhesiveness of the layer is excellent.

Apart from the above-mentioned pigment, any other filler such as silica or the like may be added to the colorant layer. The amount of the filler to be added is preferably at most 20% by mass of the binder in the colorant layer, more preferably at most 15% by mass. When containing such a filler, the strength of the colorant layer can be enhanced. When the amount of the filler is at most 20% by mass, then the ratio of the pigment in the layer can be kept good and the layer secures good light reflection (reflectivity) and good decorative design.

### (4) Method for Forming Colorant Layer

For forming the colorant layer, herein employable are a method of sticking a pigment-containing polymer sheet to the film, a method of co-extruding the colorant layer in producing the film of the invention, a coating method, etc. Of those, the coating method is preferred as simple and capable of forming a highly-uniform and thin coating layer. For the coating method, for example, usable is any known gravure coater, bar coater or the like. The solvent for the coating liquid may be water, or may also be an organic solvent such as toluene, methyl ethyl ketone or the like. However, from the viewpoint of environmental load, the solvent is preferably water.

One alone or two or more different types of such solvents may be used either singly or as combined.

### (5) Physical Properties

Preferably, the colorant layer is formed as a white layer (light reflection layer) containing a white pigment. The light reflectivity at 550 nm of the white layer is preferably at least 75%. When the reflectivity is at least 75%, then the layer is effective for returning the sunlight that has passed through the solar cell element and has not used for power generation back to the cell, therefore effectively increasing the power generation efficiency of the cell.

Preferably, the thickness of the white layer (light reflection layer) is from 1 to 20 μm, more preferably from 1 to 10 μm, even more preferably from 1.5 to 10 μm or so. When the thickness is at least 1 μm, then the layer can readily secure the necessary decorative design and reflectivity; and when at most 20 μm, the surface condition of the layer may be improved.

### —Undercoat Layer—

An undercoat layer may be provided in the solar cell protective sheet of the invention. For example, in case where a colorant layer is provided in the polyester film, the undercoat layer may be provided between the colorant layer and the substrate film. The undercoat layer may comprise a binder, a crosslinking agent, a surfactant, etc.

The binder to be in the undercoat layer includes polyesters, polyurethanes, acrylic resins, polyolefins, etc. In addition to the binder thereto, a crosslinking agent such as an epoxy-type, isocyanate-type, melamine-type, carbodiimide-type, oxazoline-type or the like crosslinking agent, a surfactant such as an anionic, nonionic or the like surfactant, and a filler such as silica or the like may be added to the undercoat layer.

The coating may be on the biaxially-stretched substrate film or may also be on a monoaxially-stretched substrate film. In this case, after coated, the substrate film may be further stretched in the direction different from the previous stretching direction. In addition, after the stretched substrate film is thus coated, the substrate film may be stretched in two directions.

Preferably, the thickness of the undercoat layer is from 0.05 μm to 2 μm, more preferably from 0.1 μm to 1.5 μm or so. When the thickness is at least 0.05 μm, the layer can readily secure the necessary adhesiveness; and when at most 2 μm, then the surface condition of the layer can be kept good.

### —Easy Adhesion Layer—

In case where the solar cell protective sheet of the invention is used for constructing a solar cell module, the film may have an easy adhesion layer on the side of the sealant on the cell-side substrate of a solar cell element sealed up with a sealant. Thus providing an easy adhesion layer capable of exhibiting adhesiveness to an adherend containing a sealant (especially ethylene/vinyl acetate copolymer) (for example, the surface of the sealant on the cell-side substrate of a solar cell element sealed up with a sealant) enhances the adhesiveness between the back sheet and the sealant.

### <Solar Cell Module>

The solar cell module of the invention contains the solar cell protective sheet of the invention.

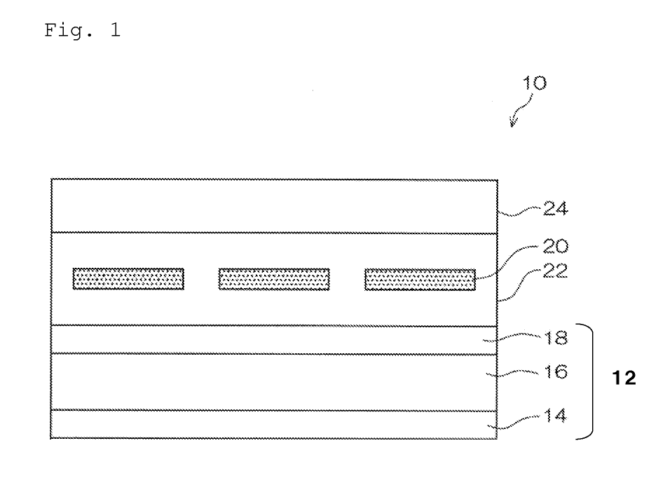

FIG. 1 shows schematically one example of the configuration of the solar cell module of the invention. The solar cell module 10 of the invention is so configured that the solar cell element 20 for converting the light energy of sunlight into electric energy is sandwiched between the transparent front substrate 24 on which sunlight falls (this may be the solar cell protective sheet of the invention) and the solar cell back sheet 12 (preferably this is the solar cell protective sheet of the invention). The space between the transparent front substrate 24 and the back sheet 12 may be sealed up with the resin 22 of, for example, ethylene-vinyl acetate copolymer or the like (so-called sealant). The solar cell module 10 of the invention has a cell-side substrate including the solar cell element 20 and the sealant 22 to seal up the solar cell element 20, and preferably, the sealant 22 of the cell-side substrate is kept in contact with the PET substrate 16 of the solar cell protective sheet 10 of the invention. More preferably, in the solar cell module 10 of the invention, the coating layer 14 of the solar cell protective sheet 12 of the invention is arranged as the outermost layer, from the viewpoint of the weather resistance of the module. The solar cell protective sheet 12 of the invention may have a colorant layer (reflection layer) 18 between the sealant 22 and the PET substrate 16 of the solar cell protective sheet 10 of the invention.

The other parts than the solar cell module, the solar cell element and the back sheet are described, for example, in “Sunlight Power Generation System Constituent Materials” (edited by Eiichi Sugimoto, published by Kogyo Chosakai Publishing, 2008).

The transparent substrate may have light transmittance capable of transmitting sunlight therethrough, and may be suitably selected from light-transmitting substrates. From the viewpoint of power generation efficiency, those having high light transmittance are preferred, and preferred examples of the substrates of the type include glass substrates, transparent resins such as acrylic resins, etc.

As the solar cell element, herein usable is any one for various known solar cell elements, including, for example, silicon materials of single-crystal silicon, polycrystal silicon, amorphous silicon, etc.; III-V Group or II-VI Group compound semiconductor materials of copper-indium-gallium-selenium, copper-indium-selenium, cadmium-tellurium, gallium-arsenic, etc.

### EXAMPLES

The characteristics of the invention are described further concretely with reference to the following Examples.

In the following Examples, the material used, its amount and ratio, the details of the treatment and the treatment process may be suitably modified or changed not overstepping the spirit and the scope of the invention. Accordingly, the invention should not be limitatively interpreted by the Examples mentioned below.

Unless otherwise specifically indicated, “part” is by mass.

### (Measurement Methods)

### —Retention of Elongation at Break—

The sample is cut into strips each having a width of 10 mm and a length of 200 mm, thereby preparing test strips A and B.

The test strip A is conditioned in an atmosphere at 25° C. and a relative humidity of 60% for 24 hours, and then tested in a tensile test using Tensilon (ORIENTEC's RTC-1210A). The length of the sample to be stretched is 10 cm and the pulling rate is 20 mm/min. The elongation at break of the test strip A obtained in this evaluation is referred to as L0.

Separately, the test strip B is subjected to wet heat treatment in an atmosphere at 120° C. and a relative humidity of 100% for 50 hours, and tested in the same tensile test as that for the test strip A. The elongation at break of the test strip B is referred to as L1.

Based on the data L0 and L1 of the elongation at break of the sample, as measured according to the measurement method, the retention of elongation at break (%) of the sample is computed according to the following equation.

Retention of Elongation at Break (%)=L1/L0×100

The results are shown in Table 1 and Table 2 in the column of retention of elongation at break therein.

### (2) Adhesiveness Before Wet Heat Aging

Using a single-edged knife, the surface of the fluoropolymer layer of the sample is cross-cut longitudinally and laterally each in 6 lines at intervals of 3 mm to thereby form 25 cross-cuts in all. A Mylar tape (adhesive polyester tape) is stuck to the cross-cut surface, and peeled by hand in the 180-degree direction along the surface of the sample. Based on the number of the peeled cross-cuts in the test, the adhesion power of the back layer is evaluated and ranked according to the following evaluation criteria. The samples on the evaluation rank 4 or 5 are practicable ones.

### <Evaluation Criteria>

5: No cross-cut peeled (0 cross-cut peeled).
4: From 0 to less than 0.5 cross-cuts peeled.
3: From 0.5 to less than 2 cross-cuts peeled.
2: From 2 to less than 10 cross-cuts peeled.
1: 10 or more cross-cuts peeled.
(3) Adhesiveness after Wet Heat Aging

The sample is kept under the environmental condition at 120° C. and a relative humidity of 100% for 50 hours, and then conditioned in the environment at 25° C. and a relative humidity of 60% for 1 hour. Subsequently, the adhesion power of the fluoropolymer layer is evaluated according to the same evaluation method as that for the above-mentioned “Adhesiveness before Wet Heat Aging”. The samples on the evaluation rank 3, 4 or 5 are practicable ones.

### (4) Thermal Shrinkage

The sample film is cut to give rectangular test pieces of 5 cm×15 cm. Those cut in parallel to MD (machine direction, or that is, film-traveling direction) to have a side of 15 cm are referred to as MD samples, and those cut in parallel to TD (transverse direction, or that is, direction perpendicular to the film-traveling direction) to have a side of 15 cm are referred to as TD samples; and 3 MD samples and 3 TD samples are prepared. These samples are cut out at every site of five equal parts of the film width, and 15 MD samples and 15 TD samples are thus prepared in total.

Each sample is conditioned at 25° C. and at a relative humidity of 60% for 3 hours or more, a pair of holes each having a base length of 10 cm are formed therein, and the distance between the holes is measured with a pin gauge (this is referred to as L1).

Each sample is heat-treated under no tension in an air temperature-controlled bath at 150° C. for 30 minutes. Subsequently, each sample is conditioned at 25° C. and at a relative humidity of 60% for 3 hours or more, and the distance between the holes is measured with a pin gauge (this is referred to as L2).

100×(L1−L2)/L1 indicates the thermal shrinkage (%) of each sample. The mean value of all those MD and TD samples is shown in the column of “Thermal Shrinkage” in Table 1 and Table 2.

### Example 1

### (1) Formation of Weather-Resistant Polyester Film

### (Preparation of Polyethylene Terephthalate Resin PET1)

According to the method mentioned below using a Ti catalyst, a polyester resin was produced through polymerization.

A slurry of 100 kg of high-purity terephthalic acid (by Mitsui Chemical) and 45 kg of ethylene glycol (Nippon Shokubai) was sequentially fed into an esterification tank into which about 123 kg of bis(hydroxyethyl)terephthalate had been previously put and which had been kept at a temperature of 250° C. and under a pressure of 1.2×10⁵ Pa, taking 4 hours; and after the addition, the esterification was continued for further 1 hour. Subsequently, 123 kg of the esterified product thus obtained was transferred into a polycondensation tank.

Next, ethylene glycol was added to the polycondensation tank, into which the esterified produce had been put, in an amount of 0.3% by mass relative to the polymer to be obtained. After this was stirred for 5 hours, an ethylene glycol solution of cobalt acetate and manganese acetate was added thereto in an amount of 30 ppm and 15 ppm, respectively, relative to the polymer to be obtained. After this was further stirred for 5 minutes, a 2 mass % ethylene glycol solution of a titanium alkoxide compound was added thereto, in an amount of 5 ppm relative to the polymer to be obtained. The titanium alkoxide compound used here is the titanium alkoxide compound produced in Example 1 in JP-A 2005-340616, paragraph [0083] (having a Ti content of 4.44% by mass). After 5 minutes, a 10 mass % ethylene glycol solution of ethyl diethylphosphonoacetate was added thereto in an amount of 5 ppm relative to the polymer to be obtained.

Subsequently, with stirring at 30 rpm, the low polymer was gradually heated from 250° C. to 285° C. while the pressure was lowered to 40 Pa. The time taken to reach the final temperature and the final pressure was 60 minutes each. At the time at which the reaction system had a predetermined torque (97 kg·cm), the system was purged with nitrogen and restored to a normal pressure, thereby terminating the polycondensation reaction. The time taken to reach the predetermined stirring torque from the start of depressurization was 3 hours.

The obtained polymer melt was extruded out into cold water like strands, and immediately cut to give polymer pellets (having a diameter or about 3 mm and a length of about 7 mm).

### (Formation of Polyethylene Terephthalate Substrate)

The pellets obtained in the above were polymerized in a mode of solid-phase polymerization under the condition mentioned below, and then melt kneaded at 280° C. using a double-screw extruder in a nitrogen stream atmosphere. The melt was cast onto a metal drum at 280° C., via a gear pump, a filter and a die, thereby giving an unstretched base having a thickness of about 3 mm. The chill roll was statically charged and cooled with a coolant at 10° C. The melt was solidified on the chill roll and then peeled to give an unstretched film.

Subsequently, the film was stretched three times in the longitudinal direction at 90° C., and then 3.3 times in the lateral direction at 120° C. Thus, a biaxially-stretched polyethylene terephthalate substrate having a thickness of 300 μm (hereinafter referred to as “PET1”) was obtained.

### —Solid-Phase Polymerization—

The pellets obtained in the above wee crystallized at 140° C. for 10 minutes, then dried at 170° C. for 3 hours, and polymerized in a mode of solid-phase polymerization at 230° C. for 30 hours to give a solid-phase polymerized resin. The crystallization, the drying and the solid-phase polymerization were all carried out in a nitrogen stream atmosphere. The carboxyl group content of the polyethylene terephthalate in the obtained PET1 substrate was 18 equivalents/ton.

### (2) Surface Treatment of Polyethylene Terephthalate Substrate (Itro Treatment)

One surface of the polyethylene terephthalate substrate was subjected to Itro treatment under the condition mentioned below.

Air supply, 154 L/min
Gas supply, 7 L/min
Itro treating liquid, 1 L/min
Traveling speed, 60 m/min
Distance between flame and surface, 20 mm

### (3) Formation of Coating Layer on Treated Surface of Substrate

### (4) Formation of Coating Layer (Fluoropolymer Layer)

### (Preparation of Fluoropolymer Layer-Forming Coating Liquid)

The following ingredients were mixed to prepare a fluoropolymer layer-forming coating liquid.

### (Composition of Coating Liquid)

Obbligato SW0011F (binder) (fluorobinder by AGC Coat-Tech, solid content 39% by mass) 247.8 parts by mass Carbodiimide compound (crosslinking agent) (Carbodilite V-02-L2, by Nisshinbo, solid content 40% by mass) 24.2 parts by mass
Surfactant (Naroacty CL95, by Sanyo Chemical Industry, solid content 1% by mass) 24.2 parts by mass
Distilled water 703.8 parts by mass
(Coating with Fluoropolymer Layer)

The obtained, fluoropolymer layer-forming coating liquid was applied onto the Itro-treated surface of the PET substrate so that the binder amount thereof could be 2.0 g/m², and dried at 180° C. for 1 minute to form thereon a fluoropolymer layer having a dry thickness of about 2 μm.

The obtained laminate is a solar cell protective sheet of Example 1.

### Examples 2 to 10

### Comparative Examples 1 to 10

Solar cell protective sheets of Examples 2 to 10 and Comparative Examples 1 to 10 were produced in the same manner as in Example 1, except that the type of the substrate PET, the surface treatment, the polymer, the crosslinking agent and the presence or absence of filler were changed as in the following Table 1 and Table 2. The details of some Examples and Comparative Examples are described below.

In Example 2, one surface of the polyethylene terephthalate substrate was subjected to atmospheric plasma treatment under the condition mentioned below.

While conveyed in an atmosphere of a plasma gas of air mixed with argon gas (gas pressure: 750 Torr), the surface of PET-1 was irradiated with plasma at an output discharge strength of 250 W·min/m², as generated through discharge in a high-frequency discharger having a power source frequency of 5 kHz, for 15 seconds.

In Example 3, an oxazoline compound (Epocross WS-700, by Nippon Shokubai, solid content 25%) was used as the crosslinking agent in place of the carbodiimide compound.

In Example 5, 30 parts by mass of silica (by Nissan Chemical Industry) was added as a filler to the fluoropolymer layer-forming coating liquid.

In Example 7, pellets were formed according to the same process as in Example 1 except that the solid-phase polymerization was omitted, and the pellets were formed into a biaxially-stretched polyethylene terephthalate substrate (hereinafter referred to as “PET2”) according to the same process of Example 1, (1-2). The others were the same as in Example 1, and a solar cell protective sheet of Example 7 was produced. The carboxyl group content of the polyethylene terephthalate in the PET2 substrate was 30 equivalents/ton.

In Example 8, an epoxy compound (by Nagase Chemtex, solid content 25%) was used in place of the carbodiimide compound as the crosslinking agent.

In Example 10, the tension in transferring the substrate was changed so that the thermal shrinkage of the substrate could be 0.6%. The others were the same as in Example 5, and a solar cell protective sheet of Example 10 was produced.

Comparative Example 2 is a case where ordinary flame treatment heretofore known in the art was applied to the PET substrate in place of the Itro treatment. In this, one surface of the polyethylene terephthalate was subjected to flame treatment under the condition mentioned below.

While conveyed, the surface of the PET-1 was irradiated with a flame in combustion of a mixed gas of propane gas and air of 1/17 (by volume) from a horizontal burner, for 0.5 seconds.

Comparative Example 3 is a case where the corona treatment investigated in Examples in JP-A 2010-053317 was applied to the PET substrate. In this, one surface of the polyethylene terephthalate substrate was corona-treated under the condition mentioned below.

Traveling speed: 70 m/min
Irradiation energy: 730 J/m²

In Comparative Example 4, Olester UD350 (polyurethane resin, by Mitsui Chemical, hereinafter referred to as “PU”, solid content 38%) was used in place of the above-mentioned Obbligato SW0011F to prepare a coating liquid, and the others were the same as in Example 1 to produce a solar cell protective sheet of Comparative Example 4.

In Comparative Example 10, the tension in traveling the substrate was changed so that the thermal shrinkage of the substrate could be 0.6%, and in the same manner as in Comparative Example 1, a solar cell protective sheet of Comparative Example 10 was produced.

The obtained samples were evaluated in point of the retention of elongation at break, the adhesiveness before wet heat aging, the adhesiveness after wet heat aging, and the thermal shrinkage. The results are shown in Table 1 and Table 2.

TABLE 1

| | | Example 1 | Example 2 | Example 3 | Example 4 | Example 5 | Example 6 | Example 7 | Example 8 | Example 9 | Example 10 |
|---|---|---|---|---|---|---|---|---|---|---|---|
| Substrate | Type of PET | PET1 | PET1 | PET1 | PET1 | PET1 | PET1 | PET2 | PET1 | PET1 | PET1 |
| | Surface | Itro | APP | Itro | APP | Itro | Itro | Itro | Itro | APP | Itro |
| | Treatment | | | | | | | | | | |
| Coating | Polymer | F-polymer | F-polymer | F-polymer | F-polymer | F-polymer | F-polymer | F-polymer | F-polymer | F-polymer | F-polymer |
| Layer | Crosslinking | carbodi- | carbodi- | oxazoline | oxazoline | carbodi- | oxazoline | carbodi- | epoxy | epoxy | carbodi- |
| | Agent | imide | imide | | | imide | | imide | | | imide |
| | Filler | none | none | none | none | silica | silica | none | none | none | silica |
| Evaluation | Retention of | 80% | 80% | 80% | 80% | 80% | 80% | 45% | 80% | 80% | 80% |
| | Elongation at | | | | | | | | | | |
| | Break | | | | | | | | | | |
| | Adhesiveness | 5 | 5 | 5 | 5 | 5 | 5 | 5 | 4 | 4 | 5 |
| | before Wet | | | | | | | | | | |
| | Heat Aging | | | | | | | | | | |
| | Adhesiveness | 4 | 4 | 4 | 4 | 5 | 5 | 4 | 3 | 3 | 3 |
| | after Wet | | | | | | | | | | |
| | Heat Aging | | | | | | | | | | |
| | Thermal | 0.2 | 0.2 | 0.2 | 0.2 | 0.2 | 0.2 | 0.3 | 0.3 | 0.3 | 0.6 |
| | Shrinkage | | | | | | | | | | |

TABLE 2

| | | Compar- | Compar- | Compar- | Compar- | Compar- | Compar- | Compar- | Compar- | Compar- | |
|---|---|---|---|---|---|---|---|---|---|---|---|
| | | ative | ative | ative | ative | ative | ative | ative | ative | ative | Comparative |
| | | Example 1 | Example 2 | Example 3 | Example 4 | Example 5 | Example 6 | Example 7 | Example 8 | Example 9 | Example 10 |
| Substrate | Type of PET | PET1 | PET1 | PET1 | PET1 | PET1 | PET1 | PET1 | PET1 | PET1 | PET1 |
| | Surface | none | flame | corona | Itro | APP | Itro | APP | none | none | none |
| | Treatment | | | | | | | | | | |
| Coating | Polymer | F-polymer | F-polymer | F-polymer | PU | PU | PU | PU | F-polymer | F-polymer | F-polymer |
| Layer | Crosslinking | carbodi- | carbodi- | carbodi- | carbodi- | carbodi- | oxazoline | oxazoline | epoxy | carbodi- | carbodi- |
| | Agent | imide | imide | imide | imide | imide | | | | imide | imide |
| | Filler | none | none | none | none | none | none | none | none | silica | none |
| Evaluation | Retention of | 80% | 80% | 80% | 80% | 80% | 80% | 80% | 80% | 80% | 80% |
| | Elongation | | | | | | | | | | |
| | at Break | | | | | | | | | | |
| | Adhesiveness | 3 | 4 | 4 | 4 | 4 | 4 | 4 | 3 | 4 | 3 |
| | before Wet | | | | | | | | | | |
| | Heat Aging | | | | | | | | | | |
| | Adhesiveness | 2 | 2 | 2 | 1 | 1 | 1 | 1 | 2 | 2 | 1 |
| | after Wet | | | | | | | | | | |
| | Heat Aging | | | | | | | | | | |
| | Thermal | 0.2 | 0.2 | 0.2 | 0.3 | 0.3 | 0.3 | 0.3 | 0.2 | 0.2 | 0.6 |
| | Shrinkage | | | | | | | | | | |

From Table 1 and Table 2, it is known that the solar cell protective sheets of the invention have good interlayer adhesiveness after wet heat aging. On the other hand, it is known that the sheets of Comparative Examples 1 to 3, and 8 to 10, in which the PET substrate was not surface-treated or was surface-treated in a manner different from Itro treatment or atmospheric treatment, are all bad in the adhesiveness between the PET substrate and the coating layer after wet heat aging. It is also known that the sheets of Comparative Examples 4 to 7, in which polyurethane was used in place of the fluororesin layer, are all bad in the adhesiveness between the substrate and the coating layer after wet heat aging.

### Example 11

The solar cell protective sheet sample obtained in Example 1 was used. According to the method mentioned below, a reflection layer was given to the solar cell protective sheet to construct a solar cell back sheet.

### <Reflection Layer>

### —Preparation of Reflection Layer-Forming Coating Liquid—

The following ingredients were mixed to prepare a reflection layer-forming coating liquid.

### (Composition of Coating Liquid)

Titanium dioxide dispersion used in Example 1

714.3 parts by mass

Aqueous dispersion of polyacrylic resin [binder: Julimar ET410, by Nippon Junyaku, solid content 30%]

171.4 parts by mass

Polyoxyalkylene alkyl ether [Naroacty CL95, by Sanyo Chemical Industry, solid content 1%] 26.8 parts by mass
Oxazoline compound [Epocross WS-700, by Nippon Shokubai, solid content 25%, crosslinking agent]

17.9 parts by mass

Distilled water 69.6 parts by mass

### —Formation of Reflection Layer—

The obtained coating liquid was applied onto the surface of the PET substrate opposite to the surface thereof coated with the undercoat layer and the fluoropolymer layer, and dried at 180° C. for 1 minute to form thereon, a reflection layer having a thickness of about 2 μm and having a titanium dioxide amount of 5.5 g/m².

According to the above-mentioned process, a solar cell back sheet was produced, having a laminate structure of reflection layer/PET substrate/fluoropolymer layer.

### Example 12

A reinforced glass sheet having a thickness of 3 mm, an EVA sheet (Mitsui Chemicals Fabro's SC50B), a crystal-type solar cell element, an EVA sheet (Mitsui Chemicals Fabro's SC50B) and the sample sheet (solar cell back sheet) of Example 11 were laminated in that order, and hot-pressed using a vacuum laminator (Nisshinbo's vacuum laminator) to thereby stick the reinforced glass sheet, the solar cell and the sample sheet to EVA. In this, the sample sheet was so arranged that the reflection layer thereof could be in contact with the EVA sheet.

The EVA adhesion condition was as follows.

Using a vacuum laminator, the layered sample was vacuumed at 128° C. for 3 minutes, and then pressed for 2 minutes for temporary adhesion. Subsequently, this was processed in a dry oven at 150° C. for 30 minutes for final lamination.

In the manner as above, a crystal-type solar cell module was produced. The solar cell module was tried for power generation, and exhibited good power generation performance as a solar cell.

The solar cell protective sheet of the invention is favorably used, for example, as a back-side sheet to constitute a solar cell module (this is a so-called back sheet to be arranged on the side of a solar cell element opposite to the side thereof on which sunlight falls).

While the present invention has been described in detail and with reference to specific embodiments thereof, it will be apparent to one skilled in the art that various changes and modifications can be made therein without departing from the spirit and scope thereof.

The present disclosure relates to the subject matter contained in International Application No. PCT/JP2011/075487, filed Nov. 9, 2011; and Japanese Application No. 2010-251204, filed Nov. 9, 2010, the contents of which are expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

What is claimed is:

1. A solar cell protective sheet comprising a polyethylene terephthalate-containing substrate that has been surface-treated through flame treatment with a silane compound-introduced flame or through atmospheric-pressure plasma treatment, and having, on the treated surface of the substrate, a coating layer that contains a fluoropolymer.

2. The solar cell protective sheet according to claim 1, wherein the coating layer contains a crosslinked structure derived from a carbodiimide compound-type crosslinking agent.

3. The solar cell protective sheet according to claim 1, wherein the coating layer contains a crosslinked structure derived from an oxazoline compound-type crosslinking agent.

4. The solar cell protective sheet according to claim 1, wherein the coating layer contains at least one filler.

5. The solar cell protective sheet according to claim 1, of which the elongation at break after stored under the condition at 120° C. and a relative humidity of 100% for 50 hours is at least 50% of the elongation at break thereof before storage.

6. The solar cell protective sheet according to claim 1, of which the thermal shrinkage before and after storage at 150° C. for 30 minutes is from 0 to 0.5%.

7. The solar cell protective sheet according to claim 1, wherein the treated surface of the substrate and the coating layer are kept in direct contact with each other without any adhesive or sticking agent therebetween.

8. The solar cell protective sheet according to claim 1, wherein the thickness of the coating layer is from 0.5 to 15 μm.

9. The solar cell protective sheet according to claim 1, wherein the coating layer is an outermost layer.

10. The solar cell protective sheet according to claim 1, wherein the substrate is used on the sealant side of the cell-side substrate of a solar cell element sealed up with a sealant.

11. A method for producing a solar cell protective sheet, comprising:
processing at least one surface of a polyethylene terephthalate substrate through flame treatment with a silane compound kept introduced into a flame or through plasma treatment under atmospheric pressure, and
coating the treated surface of the substrate with a fluoropolymer-containing, coating layer composition.

12. The method for producing a solar cell protective sheet according to claim 11, wherein the at least one surface of a polyethylene terephthalate substrate is processed through the flame treatment.

13. The method for producing a solar cell protective sheet according to claim 11, wherein the at least one surface of a polyethylene terephthalate substrate is processed through the plasma treatment.

14. The method for producing a solar cell protective sheet according to claim 11, wherein the coating layer composition contains at least one of a carbodiimide compound-type crosslinking agent and an oxazoline compound-type crosslinking agent.

15. The method for producing a solar cell protective sheet according to claim 11, wherein the coating layer composition contains at least one filler.

16. A solar cell protective sheet produced by:
processing at least one surface of a polyethylene terephthalate substrate through flame treatment with a silane compound kept introduced into a flame or through plasma treatment under atmospheric pressure, and
coating the treated surface of the substrate with a fluoropolymer-containing, coating layer composition.

17. Aback sheet for solar cells, containing the solar cell protective sheet of claim 1.

18. A solar cell module containing the solar cell protective sheet produced by:
processing at least one surface of a polyethylene terephthalate substrate through flame treatment with a silane compound kept introduced into a flame or through plasma treatment under atmospheric pressure, and
coating the treated surface of the substrate with a fluoropolymer-containing, coating layer composition.

19. The solar cell module according to claim 18, which comprises a solar cell element and a cell-side substrate containing a sealant for sealing the solar cell element, and wherein the sealant of the cell-side substrate is kept in contact with the substrate of the solar cell protective sheet.

20. The solar cell module according to claim 18, wherein the coating layer of the solar cell protective sheet is arranged as the outermost layer.
